(19) United States
(12) Patent Application Publication
(10) Pub. No.: US 2025/0062231 A1
(43) Pub. Date: Feb. 20, 2025

(54) WIRING SUBSTRATE

(71) Applicant: SHINKO ELECTRIC INDUSTRIES CO., LTD., Nagano-shi (JP)

(72) Inventors: Takashi NISHIYAMA, Nagano-shi (JP); Yoshiki AKIYAMA, Matsumoto-shi (JP)

(21) Appl. No.: 18/795,429

(22) Filed: Aug. 6, 2024

(30) Foreign Application Priority Data
Aug. 18, 2023 (JP) 2023-133227

(51) Int. Cl. H01L 23/528; H01L 23/532; H01L 23/538

(52) U.S. Cl. CPC H01L 23/5283; H01L 23/53295; H01L 23/5383

(57) ABSTRACT

A wiring substrate includes a first wiring layer, a first insulating layer, and a second wiring layer. The first insulating layer covers the first wiring layer. The second wiring layer is formed on an upper surface of the first insulating layer and is electrically connected to the first wiring layer. The upper surface of the first insulating layer includes a first roughened surface, and a second roughened surface having a greater roughness than the first roughened surface. The second roughened surface includes a wrinkle pattern resulting from buckling. A volume percent of the first wiring layer located in a first region that overlaps the first roughened surface in plan view is greater than a volume percent of the first wiring layer located in a second region that overlaps the second roughened surface in plan view.

### CROSS-REFERENCE TO RELATED APPLICATIONS

This application is based upon and claims the benefit of priority from prior Japanese Patent Application No. 2023-133227, filed on Aug. 18, 2023, the entire contents of which are incorporated herein by reference.

### BACKGROUND

### 1. Field

The following description relates to a wiring substrate and a method for manufacturing a wiring substrate.

### 2. Description of Related Art

A typical wiring substrate, on which electronic components such as semiconductor elements are mounted, includes wiring layers and insulating layers stacked on both upper and lower surfaces of a core substrate by a build-up process in order to increase the density of wiring patterns. In this type of wiring substrate, it has been suggested that a high-density wiring layer including an insulating layer formed from a photosensitive resin be arranged on a low-density wiring layer including an insulating layer formed from a thermosetting resin. Japanese Laid-Open Patent Publication No. 2014-225632 discloses such a wiring substrate.

### SUMMARY

In the wiring substrate, it is desired that roughened surfaces having different roughnesses be readily formed on the same plane of an insulating layer.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a wiring substrate includes a first wiring layer, a first insulating layer, and a second wiring layer. The first insulating layer covers the first wiring layer. The second wiring layer is formed on an upper surface of the first insulating layer and is electrically connected to the first wiring layer. The upper surface of the first insulating layer includes a first roughened surface, and a second roughened surface having a greater roughness than the first roughened surface. The second roughened surface includes a wrinkle pattern resulting from buckling. A volume percent of the first wiring layer located in a first region that overlaps the first roughened surface in plan view is greater than a volume percent of the first wiring layer located in a second region that overlaps the second roughened surface in plan view.

Other features and aspects will be apparent from the following detailed description, the drawings, and the claims.

### BRIEF DESCRIPTION OF THE DRAWINGS

FIG. 1 is a schematic cross-sectional view of a wiring substrate in accordance with an embodiment.

FIG. 2 is an enlarged cross-sectional view of part of the wiring substrate enclosed by single-dashed lines in FIG. 1.

FIG. 3 is a schematic plan view of a wrinkle pattern in accordance with the embodiment.

FIG. 4 is a schematic cross-sectional view of a semiconductor device including the wiring substrate illustrated in FIG. 1.

FIGS. 5, 6, 7, 8, 9, 10, 11, 12, 13, 14, 15, 16, 17, and 18 are schematic cross-sectional views illustrating a method for manufacturing the wiring substrate illustrated in FIG. 1.

FIG. 19 is a schematic cross-sectional view illustrating a wiring substrate of a modified example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

An embodiment will now be described with reference to the drawings.

In the accompanying drawings, elements are illustrated for simplicity and clarity and have not necessarily been drawn to scale. To facilitate understanding, hatching lines may not be shown or may be replaced by shadings in the cross-sectional views.

### Overall Structure of Wiring Substrate 10

A wiring substrate 10 includes a wiring structure 11, a wiring structure 12, and a solder resist layer 13. The wiring structure 12 is formed on an upper surface of the wiring structure 11. The solder resist layer 13 is formed on a lower surface of the wiring structure 11. The wiring structure 11 is, for example, a low-density wiring layer that includes a wiring layer having a lower wiring density than the wiring structure 12. The wiring structure 12 is, for example, a high-density wiring layer that includes a wiring layer having a higher wiring density than the wiring structure 11. The wiring substrate 10 may have any planar shape and any size. The planar shape of the wiring substrate 10 may be, for example, a quadrangle that is approximately 20 mm×20 mm to 40 mm×40 mm.

### Wiring Structure 11

The wiring structure 11 includes a core substrate 20. The core substrate 20 is located, for example, at a central part of the wiring structure 11 in a thickness-wise direction. The material of the core substrate 20 may be, for example, a glass epoxy substrate obtained by impregnating a glass cloth (glass woven cloth), which is a reinforcement material, with a thermosetting insulating resin, which includes an epoxy resin as a main component, and curing the resin. The reinforcement material is not limited to a glass cloth and may be, for example, a glass non-woven cloth, an aramid woven cloth, an aramid non-woven cloth, a liquid crystal polymer (LCP) woven cloth, or an LCP non-woven cloth. The thermosetting insulating resin is not limited to epoxy resin and may be, for example, a resin material such as polyimide resin or cyanate resin. The core substrate 20 may contain, for example, a filler such as silica (SiO₂) or alumina (Al₂O₃). The core substrate 20 may have a thickness of, for example, approximately 800 μm to 2000 μm.

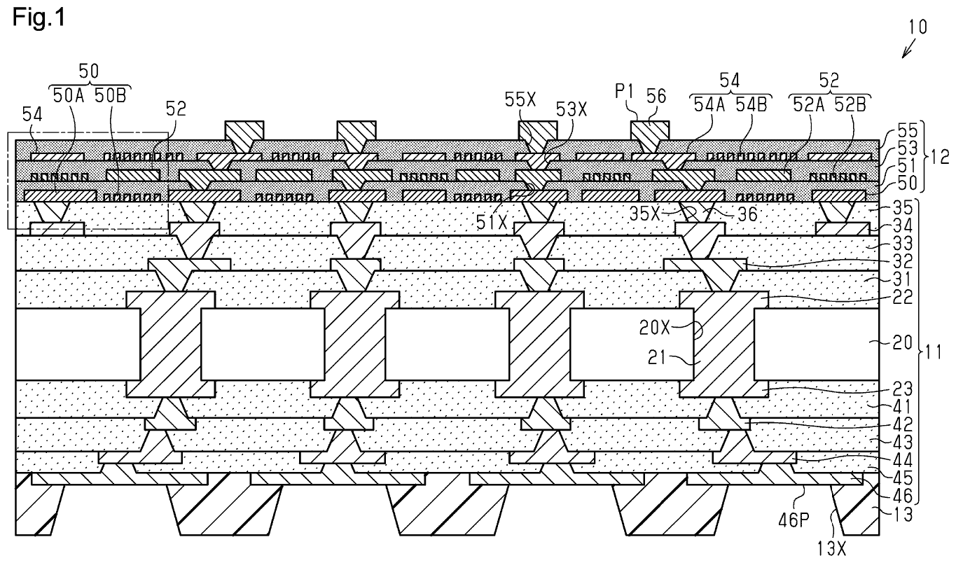

The core substrate 20 includes through holes 20X at given locations (four locations in FIG. 1). The through holes 20X extend through the core substrate 20 in the thickness-wise direction. A through-electrode 21 is formed in each through hole 20X and extends through the core substrate 20 in the thickness-wise direction. The through holes 20X are, for example, filled with the through-electrodes 21. The material of the through-electrodes 21 may be, for example, copper (Cu) or a copper alloy.

A wiring layer 22 is formed on an upper surface of the core substrate 20. A wiring layer 23 is formed on a lower surface of the core substrate 20. The wiring layers 22 and 23 are electrically connected to each other by the through-electrodes 21. The material of the wiring layers 22 and 23 may be, for example, copper or a copper alloy. The wiring layers 22 and 23 may each have a thickness of, for example, approximately 15 μm to 35 μm. The wiring layers 22 and 23 may each have a line-and-space (L/S) of, for example, approximately 20 μm/20 μm. Here, “line” (L) in the term “line-and-space” indicates a wiring width and “space” (S) indicates an interval between adjacent wiring parts. For example, when the line-and-space (L/S) is described as 20 μm/20 μm, it means that the wiring width (i.e., line) is 20 μm and the interval (i.e., space) between adjacent wiring parts is 20 μm.

An insulating layer 31, a wiring layer 32, an insulating layer 33, a wiring layer 34, an insulating layer 35, and via wiring 36 are sequentially stacked on the upper surface of the core substrate 20. The material of the insulating layers 31, 33, and 35 may be, for example, a non-photosensitive insulating resin including a thermosetting resin, such as an epoxy resin or a polyimide resin, as a main component. The insulating layers 31, 33, and 35 may contain, for example, a filler such as silica or alumina. The material of the wiring layers 32 and 34 and the via wiring 36 may be, for example, copper or a copper alloy. The insulating layers 31, 33, and 35 may each have a thickness of, for example, approximately 20 μm to 45 μm. The wiring layers 32 and 34 may each have a thickness of, for example, approximately 15 μm to 35 μm. The wiring layers 32 and 34 may each have a line-and-space (L/S) of approximately 20 μm/20 μm.

The insulating layer 31 is formed on the upper surface of the core substrate 20 and covers the wiring layer 22. The wiring layer 32 is formed on an upper surface of the insulating layer 31. The wiring layer 32 is, for example, formed integrally with via wiring extending through the insulating layer 31 in the thickness-wise direction and is electrically connected to the wiring layer 22 by the via wiring. The insulating layer 33 is formed on the upper surface of the insulating layer 31 and covers the wiring layer 32. The wiring layer 34 is formed on an upper surface of the insulating layer 33. The wiring layer 34 is, for example, formed integrally with via wiring extending through the insulating layer 33 in the thickness-wise direction and is electrically connected to the wiring layer 32 by the via wiring.

The insulating layer 35 is the uppermost insulating layer of the wiring structure 11. The insulating layer 35 is formed on the upper surface of the insulating layer 33 and covers the wiring layer 34. The insulating layer 35 includes through holes 35X extending through the insulating layer 35 in the thickness-wise direction and exposing parts of an upper surface of the wiring layer 34.

An upper surface of the insulating layer 35 is a smooth surface (low roughness surface) having relatively few irregularities. The upper surface of the insulating layer 35 is, for example, a polished surface. The upper surface of the insulating layer 35 is set to have an arithmetic mean roughness Ra of, for example, approximately 15 nm to 40 nm. The arithmetic mean roughness Ra is a type of numerical value that represents surface roughness, and is obtained by measuring absolute values of various heights from a surface, which serves as the average line, within a measurement region and arithmetically averaging these values.

The via wiring 36 is formed in each through hole 35X. The via wiring 36 electrically connects the wiring layer 34 and a wiring layer 50 formed on the upper surface of the insulating layer 35. The through hole 35X is filled with the via wiring 36. The via wiring 36 is shaped in correspondence with the through hole 35X. The via wiring 36 is tapered such that its diameter decreases from the upper side (side close to wiring layer 50) toward the lower side (side close to wiring layer 34) in FIG. 1. The via wiring 36 has the form of, for example, a reversed truncated cone so that its upper end surface has a larger diameter than its lower end surface. The upper end surface of the via wiring 36 is exposed from the insulating layer 35. The upper end surface of the via wiring 36 is, for example, flush with the upper surface of the insulating layer 35. The upper end surface of the via wiring 36 is, for example, a polished surface. The diameter of the upper end surface of the via wiring 36 may be, for example, approximately 60 μm to 70 μm.

An insulating layer 41, a wiring layer 42, an insulating layer 43, a wiring layer 44, an insulating layer 45, and a wiring layer 46 are sequentially stacked on the lower surface of the core substrate 20. The material of the insulating layers 41, 43, and 45 may be, for example, a non-photosensitive insulating resin including a thermosetting resin, such as an epoxy resin or a polyimide resin, as a main component. The insulating layers 41, 43, and 45 may contain, for example, a filler such as silica or alumina. The material of the wiring layers 42, 44, and 46 may be, for example, copper or a copper alloy. The insulating layers 41, 43, and 45 may each have a thickness of, for example, approximately 20 μm to 45 μm. The wiring layers 42, 44, and 46 may each have a thickness of, for example, approximately 15 μm to 35 μm. The wiring layers 42, 44, and 46 may each have a line-and-space (L/S) of approximately 20 μm/20 μm.

The insulating layer 41 is formed on the lower surface of the core substrate 20 and covers the wiring layer 23. The wiring layer 42 is formed on a lower surface of the insulating layer 41. For example, the wiring layer 42 is formed integrally with via wiring extending through the insulating layer 41 in the thickness-wise direction and is electrically connected to the wiring layer 23 by the via wiring. The insulating layer 43 is formed on the lower surface of the insulating layer 41 and covers the wiring layer 42. The wiring layer 44 is formed on a lower surface of the insulating layer 43. For example, the wiring layer 44 is formed integrally with via wiring extending through the insulating layer 43 in the thickness-wise direction and is electrically connected to the wiring layer 42 by the via wiring. The insulating layer 45 is formed on the lower surface of the insulating layer 43 and covers the wiring layer 44. The insulating layer 45 is the lowermost insulating layer of the wiring structure 11. The wiring layer 46 is formed on a lower surface of the insulating layer 45. The wiring layer 46 is the lowermost wiring layer of the wiring structure 11. For example, the wiring layer 46 is formed integrally with via wiring extending through the insulating layer 45 in the thickness-wise direction and is electrically connected to the wiring layer 44 by the via wiring.

### Structure of Solder Resist Layer 13

The solder resist layer 13 is the outermost insulating layer (lowermost insulating layer) of the wiring substrate 10. The solder resist layer 13 is formed on the lower surface of the wiring structure 11. In the example illustrated in FIG. 1, the solder resist layer 13 is formed on the lower surface of the insulating layer 45 of the wiring structure 11 and covers the wiring layer 46. The material of the solder resist layer 13 may be, for example, an insulating resin including a photosensitive resin, such as a phenol resin or a polyimide resin, as a main component. The solder resist layer 13 may contain, for example, a filler such as silica or alumina.

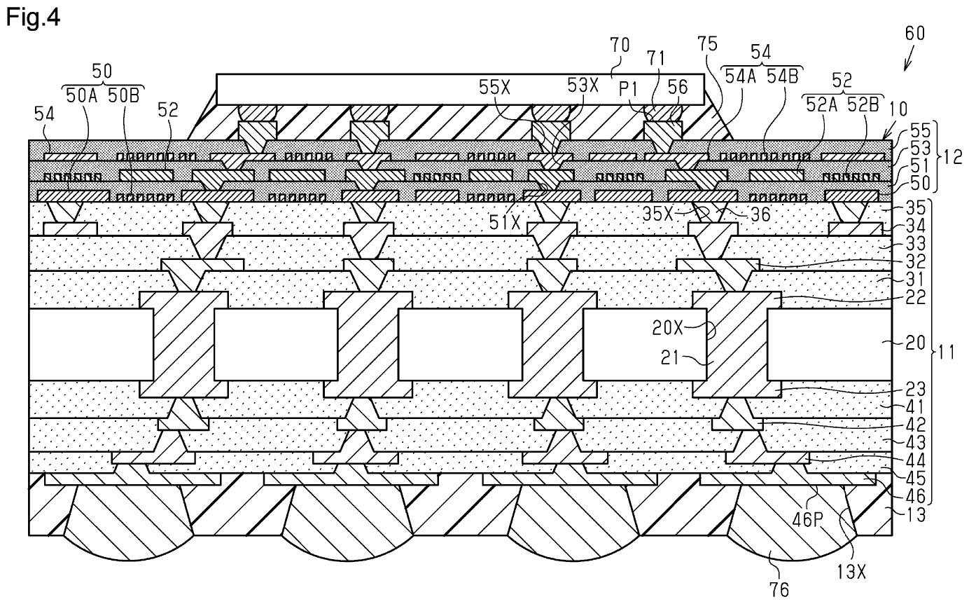

The solder resist layer 13 includes openings 13X that expose parts of the wiring layer 46 as external connection pads 46P. The external connection pads 46P are connected to external connection terminals 76 (refer to FIG. 4) used when mounting the wiring substrate 10 on a mounting substrate such as a motherboard.

A surface-processed layer is formed, if necessary, on a lower surface of the wiring layer 46 exposed at the bottom of each opening 13X. Examples of the surface-processed layer include a gold (Au) layer, a nickel (Ni) layer/Au layer (metal layer in which Ni layer serves as bottom layer, and Au layer is formed on Ni layer), an Ni layer/palladium (Pd) layer/Au layer (metal layer in which Ni layer serves as bottom layer, and Ni layer and Pd layer are sequentially formed on Au layer), or the like. Further examples of the surface-processed layer include an Ni layer/Pd layer (metal layer in which Ni layer serves as bottom layer, and Pd layer is formed on Ni layer), a Pd layer/Au layer (metal layer in which Pd layer serves as bottom layer, and Au layer is formed on Pd layer), or the like. An Au layer is a metal layer formed from Au or an Au alloy, an Ni layer is a metal layer formed from Ni or an Ni alloy, and a Pd layer is a metal layer formed from Pd or a Pd alloy. An Au layer, an Ni layer, and a Pd layer may each be, for example, a metal layer formed by an electroless plating process (electroless plating metal layer) or a metal layer formed by an electrolytic plating process (electrolytic plating metal layer). Alternatively, the surface-processed layer may be an organic solderability preservative (OPS) film formed by performing an anti-oxidation process, such as an OSP process, on the lower surface of the wiring layer 46 exposed from each opening 13X. The OSP film may be an organic coating of an azole compound, an imidazole compound, or the like. When a surface-processed layer is formed on the lower surface of the wiring layer 46, the surface-processed layer will act as the external connection pad 46P. The wiring layer 46 exposed from the opening 13X (or surface-processed layer, if surface-processed layer is formed on wiring layer 46) may be used as an external connection terminal.

The external connection pad 46P and the opening 13X may have any planar shape and any size. The planar shapes of the external connection pad 46P and the opening 13X may each be, for example, a circle having a diameter of approximately 200 μm to 300 μm.

### Wiring Structure 12

The wiring structure 12 has a structure in which the wiring layer 50, an insulating layer 51, a wiring layer 52, an insulating layer 53, a wiring layer 54, an insulating layer 55, and a wiring layer 56 are sequentially stacked on the upper surface of the insulating layer 35.

The material of the wiring layers 50, 52, 54, and 56 may be, for example, copper or a copper alloy. The material of the insulating layers 51, 53, and 55, may be, for example, a photosensitive insulating resin including a phenol resin, a polyimide resin, or the like, as a main component. Preferably, the material of the insulating layers 51, 53, and 55 does not contain a filler such as silica or alumina.

Each of the wiring layers 50, 52, 54, and 56 is thinner than each of the wiring layers 22, 23, 32, 34, 42, 44, and 46 of the wiring structure 11. The wiring layers 50, 52, and 54 may each have a thickness of, for example, approximately 1 μm to 5 μm. The wiring layer 56 may have a thickness of, for example, approximately 10 μm to 15 μm. The wiring layers 50, 52, 54, and 56 may each have a line-and-space (L/S) of approximately 2 μm/2 μm. Each of the insulating layers 51, 53, and 55 is thinner than each of the insulating layers 31, 33, 35, 41, 43, and 45 of the wiring structure 11. The insulating layers 51, 53, and 55 may each have a thickness of, for example, approximately 5 μm to 15 μm.

The wiring layer 50 is formed on the upper surface of the insulating layer 35 and is connected to the upper end surface of the via wiring 36. Part of a lower surface of the wiring layer 50 is in contact with the upper end surface of the via wiring 36 so that the wiring layer 50 is electrically connected to the via wiring 36. Although the wiring layer 50 is electrically connected to the via wiring 36, the wiring layer 50 and the via wiring 36 are not integrated with each other. The wiring layer 50 includes, for example, a seed layer formed on the upper end surface of the via wiring 36 and a metal layer formed on the seed layer.

The wiring layer 50 includes, for example, a wiring pattern 50A and a wiring pattern 50B on the same plane. The wiring pattern 50A and the wiring pattern 50B differ from each other, for example, in volume. The wiring pattern 50A has a greater volume than the wiring pattern 50B.

The wiring pattern 50A has, for example, a greater surface area (e.g., area of upper surface) than the wiring pattern 50B. The wiring pattern 50A is, for example, a plane layer (e.g., power plane or GND plane) or a land. The wiring pattern 50A is, for example, a solid pattern. The wiring pattern 50B is finer wiring than the wiring pattern 50A. The wiring pattern 50B is fine wiring having a relatively small line-and-space (L/S) of, for example, 5 μm/5 μm or less. In the present example, the wiring pattern 50B is fine wiring in which L/S is 2 μm/2 μm or less.

The wiring pattern 50A and the wiring pattern 50B differ from each other, for example, in thickness. The wiring pattern 50A is thicker than the wiring pattern 50B. The wiring pattern 50A may have a thickness of, for example, approximately 2 μm to 5 μm. The wiring pattern 50B may have a thickness of, for example, approximately 1 μm to 2 μm.

The wiring pattern 50A and the wiring pattern 50B differ from each other, for example, in wiring density (dense/sparse). The wiring pattern 50A has a higher wiring density (i.e., dense) than the wiring pattern 50B. In other words, the wiring pattern 50B has a lower wiring density (i.e., sparse) than the wiring pattern 50A.

A volume ratio between a volume of metal (copper) used as the wiring layer 50 and a volume of resin used as the insulating layer 51 differs between a high-density region (i.e., high-density wiring region) in which the wiring pattern 50A is formed and a low-density region (i.e., low-density wiring region) in which the wiring pattern 50B is formed. In the high-density region in which the wiring pattern 50A is formed, the copper ratio is higher and the resin ratio is lower than those in the low-density region in which the wiring pattern 50B is formed. In other words, in the high-density region in which the wiring pattern 50A is formed, a volume percent of the wiring layer 50 is greater than that in the low-density region in which the wiring pattern 50B is formed. The volume percent of the wiring layer 50 is a ratio of a volume of the entire wiring layer 50 included in a particular region to a volume of the entire particular region (i.e., total volume of entire wiring layer 50 and entire insulating layer 51 in particular region).

The insulating layer 51 is formed on the upper surface of the insulating layer 35 and covers the wiring layer 50. The insulating layer 51 includes through holes 51X extending through the insulating layer 51 in the thickness-wise direction and exposing parts of an upper surface of the wiring layer 50.

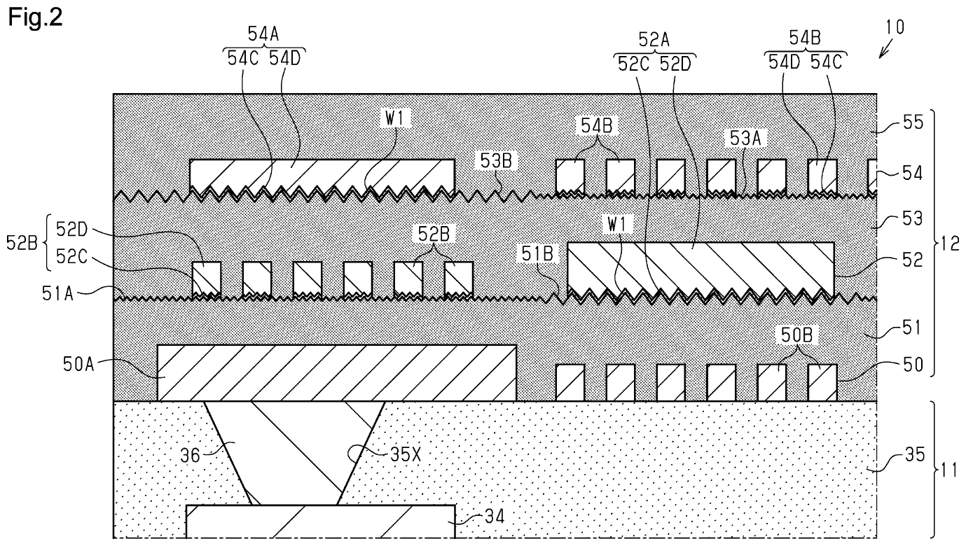

As illustrated in FIG. 2, an upper surface of the insulating layer 51 includes a roughened surface 51A and a roughened surface 51B. The roughened surface 51A has a smaller surface roughness than the roughened surface 51B. Thus, the upper surface of the insulating layer 51 includes the roughened surfaces 51A and 51B having different roughnesses on the same plane. The roughened surface 51A may have an arithmetic mean height Sa of, for example, 200 nm or less. The roughened surface 51B may have an arithmetic mean height Sa of, for example, 2 μm or less. The arithmetic mean height Sa is a type of numerical value that represents surface roughness, and is a parameter obtained by expanding an arithmetic mean roughness Ra of a line to a surface. The arithmetic mean height Sa is a parameter that indicates an average of absolute values of height differences from the average surface at measurement points in a reference region.

The roughened surface 51A is formed on the upper surface of the insulating layer 51 that is located above the wiring pattern 50A. The roughened surface 51A overlaps the wiring pattern 50A in plan view. The roughened surface 51A overlaps the high-density region in which the wiring pattern 50A is arranged in plan view. The roughened surface 51B is formed on the upper surface of the insulating layer 51 that is located above the wiring pattern 50B. The roughened surface 51B overlaps the wiring pattern 50B in plan view. The roughened surface 51B overlaps the low-density region in which the wiring pattern 50B is arranged in plan view.

In other words, the volume percent of the wiring layer 50 located in a first region that overlaps the roughened surface 51A in plan view (wiring pattern 50A) is greater than the volume percent of the wiring layer 50 located in a second region that overlaps the roughened surface 51B in plan view (wiring pattern 50B). That is, in the first region (i.e., high-density region) located immediately below the roughened surface 51A, the volume percentage of the wiring pattern 50A is higher than the volume percentage of the insulating layer 51. On the other hand, in the second region (i.e., low-density region) located immediately below the roughened surface 51B, the volume percentage of the insulating layer 51 is higher than the volume percentage of the wiring pattern 50B.

The roughened surface 51A is, for example, a roughened surface formed by performing a roughening treatment, such as a desmear process, on the upper surface of the insulating layer 51. The roughened surface 51A includes, for example, ridges and valleys at random. In FIG. 2, to facilitate understanding, the roughened surfaces 51A, 51B, 53A, and 53B are illustrated as uneven surfaces with a certain regularity.

The roughened surface 51B is a roughened surface formed by buckling. The roughened surface 51B includes, for example, ridges and valleys at random. The roughened surface 51B includes a wrinkle pattern W1 resulting from buckling. The wrinkle pattern W1 has, for example, an undulated cross-sectional structure.

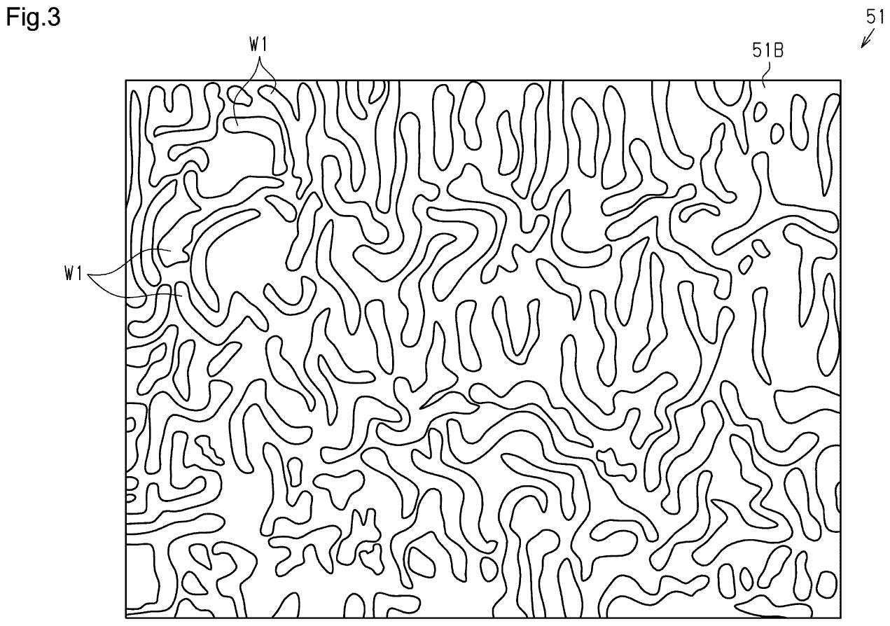

As illustrated in FIG. 3, for example, the wrinkle pattern W1 includes meandering wrinkles in plan view. The wrinkle pattern W1 includes, for example, curved wrinkles in plan view. The wrinkle pattern W1 includes, for example, serpentine wrinkles in plan view. The wrinkle pattern W1 includes, for example, wrinkles extending in random directions in plan view. The wrinkle pattern W1 is, for example, maze-like in plan view.

As illustrated in FIG. 1, the wiring layer 52 is formed on the upper surface of the insulating layer 51. The wiring layer 52 is, for example, electrically connected to the wiring layer 50 by via wiring filling the through holes 51X. The wiring layer 52 is, for example, formed integrally with the via wiring filling the through holes 51X.

As illustrated in FIG. 2, the wiring layer 52 includes, for example, a wiring pattern 52A and a wiring pattern 52B on the same plane. The wiring pattern 52A and the wiring pattern 52B differ from each other, for example, in volume. The wiring pattern 52A has a greater volume than the wiring pattern 52B.

The wiring pattern 52A has, for example, a greater surface area (e.g., area of upper surface) than the wiring pattern 52B. The wiring pattern 52A is, for example, a plane layer or a land. The wiring pattern 52A is, for example, a solid pattern. The wiring pattern 52B is finer wiring than the wiring pattern 52A. The wiring pattern 52B is fine wiring having a relatively small line-and-space (L/S) of, for example, 5 μm/5 μm or less. In the present example, the wiring pattern 52B is fine wiring in which L/S is 2 μm/2 μm or less.

The wiring pattern 52A and the wiring pattern 52B differ from each other, for example, in thickness. The wiring pattern 52A is thicker than the wiring pattern 52B. The wiring pattern 52A may have a thickness of, for example, approximately 2 μm to 5 μm. The wiring pattern 52B may have a thickness of, for example, approximately 1 μm to 2 μm.

The wiring pattern 52A and the wiring pattern 52B differ from each other, for example, in wiring density. The wiring pattern 52A has a higher wiring density (i.e., dense) than the wiring pattern 52B. The wiring pattern 52B has a lower wiring density (i.e., sparse) than the wiring pattern 52A.

A volume ratio between a volume of metal (copper) used as the wiring layer 52 and a volume of resin used as the insulating layer 53 differs between a high-density region (i.e., high-density wiring region) in which the wiring pattern 52A is formed and a low-density region (i.e., low-density wiring region) in which the wiring pattern 52B is formed. In the high-density region in which the wiring pattern 52A is formed, the copper ratio is higher and the resin ratio is lower than those in the low-density region in which the wiring pattern 52B is formed. In other words, in the high density region in which the wiring pattern 52A is formed, a volume percent of the wiring layer 52 is greater than that in the low density region in which the wiring pattern 52B is formed. The volume percent of the wiring layer 52 is a ratio of a volume of the entire wiring layer 52 included in a particular region to a volume of the entire particular region (i.e., total volume of entire wiring layer 52 and entire insulating layer 53 in particular region).

The wiring pattern 52A is formed on the roughened surface 51B. The wiring pattern 52A overlaps, for example, the wiring pattern 50B in plan view. The wiring pattern 52B is formed on the roughened surface 51A. The wiring pattern 52B overlaps, for example, the wiring pattern 50A in plan view. In the region (i.e., low-density region) located immediately above the roughened surface 51A, the volume percentage of the insulating layer 52 is higher than the volume percentage of the wiring pattern 52B. On the other hand, in the region (i.e., high-density region) located immediately above the roughened surface 51B, the volume percentage of the wiring pattern 52A is higher than the volume percentage of the insulating layer 52.

The wiring layer 52, that is, the wiring patterns 52A and 52B, includes a seed layer 52C and a metal layer 52D. The seed layer 52C is formed on the upper surface of the insulating layer 51. The metal layer 52D is formed on an upper surface of the seed layer 52C. The seed layer 52C (second seed layer) of the wiring pattern 52A is shaped in conformance with the roughened surface 51B. The metal layer 52D (second metal layer) of the wiring pattern 52A is formed on the seed layer 52C, which extends along the roughened surface 51B. The seed layer 52C (first seed layer) of the wiring pattern 52B is shaped in conformance with the roughened surface 51A. The metal layer 52D (first metal layer) of the wiring pattern 52B is formed on the seed layer 52C, which extends along the roughened surface 51A.

The seed layer 52C may be, for example, a metal film formed by sputtering (sputtered film). The seed layer 52C formed by sputtering may be, for example, a metal film having a double-layered structure in which a titanium (Ti) layer composed of Ti and a Cu layer composed of Cu are sequentially stacked on the upper surface of the insulating layer 51 by sputtering. In this case, the thickness of the Ti layer may be, for example, approximately 20 nm to 50 nm, and the thickness of the Cu layer may be, for example, approximately 100 nm to 300 nm. The Ti layer acts as a metal barrier film that inhibits dispersion of copper from the Cu layer or the metal layer 52D (e.g., Cu layer) to the insulating layer 51. The material of the metal film acting as the metal barrier film is not limited to Ti and may be titanium nitride (TiN), tantalum nitride (TaN), tantalum (Ta), chromium (Cr), or the like. Alternatively, the seed layer 52C may be, for example, an electroless plating metal film formed by electroless plating. The seed layer 52C formed by electroless plating may be a metal film having a single-layered structure of a Cu layer.

The metal layer 52D entirely covers the upper surface of the seed layer 52C. The metal layer 52D may be, for example, an electrolytic plating metal layer. The material of the metal layer 52D may be, for example, copper or a copper alloy.

In an example, the seed layer 52C is formed to be consistent in thickness in the wiring patterns 52A and 52B, and the metal layer 52D is formed to differ in thickness in the wiring patterns 52A and 52B.

As illustrated in FIG. 1, the insulating layer 53 is formed on the upper surface of the insulating layer 51 and covers the wiring layer 52. The insulating layer 53 includes through holes 53X extending through the insulating layer 53 in the thickness-wise direction and exposing parts of an upper surface of the wiring layer 52.

As illustrated in FIG. 2, the upper surface of the insulating layer 53 includes a roughened surface 53A and a roughened surface 53B. The roughened surface 53A has a smaller surface roughness than the roughened surface 53B. Thus, the upper surface of the insulating layer 53 includes the roughened surfaces 53A and 53B having different roughnesses on the same plane. The roughened surface 53A may have an arithmetic mean height Sa of, for example, 200 nm or less. The roughened surface 53B may have an arithmetic mean height Sa of, for example, 2 μm or less.

The roughened surface 53A is formed on the upper surface of the insulating layer 53 that is located above the wiring pattern 52A. The roughened surface 53A overlaps the wiring pattern 52A in plan view. The roughened surface 53A overlaps the high-density region in which the wiring pattern 52A is arranged in plan view. The roughened surface 53B is formed on the upper surface of the insulating layer 53 that is located above the wiring pattern 52B. The roughened surface 53B overlaps the wiring pattern 52B in plan view. The roughened surface 53B overlaps the low-density region in which the wiring pattern 52B is arranged in plan view.

The roughened surface 53A is, for example, a roughened surface formed by performing a roughening treatment, such as a desmear process, on the upper surface of the insulating layer 53. The roughened surface 53A includes, for example, ridges and valleys at random. The roughened surface 53B is a roughened surface formed by buckling. The roughened surface 53B includes ridges and valleys at random. The roughened surface 53B includes, for example, the wrinkle pattern W1 resulting from buckling, in the same manner as the roughened surface 51B.

As illustrated in FIG. 1, the wiring layer 54 is formed on the upper surface of the insulating layer 53. The wiring layer 54 is, for example, electrically connected to the wiring layer 52 by via wiring filling the through holes 53X. The wiring layer 54 is, for example, formed integrally with the via wiring filling the through holes 53X.

As illustrated in FIG. 2, the wiring layer 54 includes, for example, a wiring pattern 54A and a wiring pattern 54B on the same plane. The wiring pattern 54A has, for example, a greater surface area (e.g., area of upper surface) than the wiring pattern 54B. The wiring pattern 54A is, for example, a plane layer or a land. The wiring pattern 54A is, for example, a solid pattern. The wiring pattern 54B is, for example, finer wiring than the wiring pattern 54A. The wiring pattern 54B is a fine wiring pattern having a relatively small line-and-space (L/S) of, for example, 5 μm/5 μm or less. In the present example, the wiring pattern 54B is fine wiring in which L/S is 2 μm/2 μm or less. For example, the wiring pattern 54A and the wiring pattern 54B have the same thickness. The wiring patterns 54A and 54B may each have a thickness of, for example, approximately 1 μm to 5 μm.

The wiring pattern 54A is formed on the roughened surface 53B. The wiring pattern 54A overlaps, for example, the wiring pattern 52B in plan view. The wiring pattern 54B is formed on the roughened surface 53A. The wiring pattern 54B overlaps, for example, the wiring pattern 52A in plan view.

The wiring layer 54, that is, the wiring patterns 54A and 54B, includes a seed layer 54C and a metal layer 54D. The seed layer 54C is formed on the upper surface of the insulating layer 53. The metal layer 54D is formed on an upper surface of the seed layer 54C. The seed layer 54C of the wiring pattern 54A is shaped in conformance with the roughened surface 53B. The seed layer 54C of the wiring pattern 54B is shaped in conformance with the roughened surface 53A. The seed layer 54C may be, for example, a sputtered film or an electroless plating metal film, in the same manner as the seed layer 52C. The metal layer 54D entirely covers the upper surface of the seed layer 54C. The metal layer 54D may be, for example, an electrolytic plating metal layer, in the same manner as the metal layer 52D.

As illustrated in FIG. 1, the insulating layer 55 is formed on the upper surface of the insulating layer 53 and covers the wiring layer 54. The insulating layer 55 includes through holes 55X extending through the insulating layer 55 in the thickness-wise direction and exposing parts of an upper surface of the wiring layer 54. For example, an upper surface of the insulating layer 55 has uniform surface roughness. The upper surface of the insulating layer 55 may have an arithmetic mean height Sa of, for example, 200 nm or less.

The wiring layer 56 is formed on the upper surface of the insulating layer 55. The wiring layer 56 is electrically connected to the wiring layer 54 by via wiring filling the through holes 55X. For example, the wiring layer 56 is formed integrally with the via wirings filling the through holes 55X and includes pads P1 projecting from the upper surface of the insulating layer 55. The pad P1 may have any planar shape and any size. The planar shape of the pad P1 may be, for example, a circle having a diameter of approximately 20 μm to 30 μm. The distance between the consecutive pads P1 may be, for example, approximately 40 μm to 60 μm. The thickness of the pad P1 may be, for example, approximately 10 μm to 15 μm. The pads P1 act as electronic component mounting pads for electrical connection to an electronic component such as a semiconductor chip.

A surface-processed layer may be formed, if necessary, on the surfaces (upper and side surfaces or upper surface only) of the pads P1. Examples of the surface-processed layer include an OSP film or a metal layer, such as an Au layer, an Ni layer/Au layer, an Ni layer/Pd layer/Au layer, an Ni layer/Pd layer, or a Pd layer/Au layer.

### Structure of Semiconductor Device 60

The structure of a semiconductor device 60 will now be described with reference to FIG. 4.

The semiconductor device 60 includes the wiring substrate 10, one or more semiconductor chips 70, an underfill resin 75, and the external connection terminals 76.

The semiconductor chip 70 is flip-chip mounted on the wiring substrate 10. For example, bumps 71 formed on a circuit formation surface (lower surface) of the semiconductor chip 70 are bonded to the pads P1 of the wiring substrate 10 so that the semiconductor chip 70 is electrically connected to the wiring layer 56 by the bumps 71.

The semiconductor chip 70 may be, for example, a logic chip such as a central processing unit (CPU) chip or a graphics processing unit (GPU) chip. Alternatively, the semiconductor chip 70 may be, for example, a memory chip such as a dynamic random access memory (DRAM) chip, a static random access memory (SRAM) chip, or a flash memory chip. The semiconductor chips 70 including combinations of logic chips and memory chips may be mounted on the wiring substrate 10.

The dimensions of the semiconductor chip 70 may be, for example, approximately 3 mm×3 mm to 12 mm×12 mm in plan view. The semiconductor chip 70 may have a thickness of, for example, approximately 50 μm to 100 μm.

The bumps 71 may be, for example, gold bumps or solder bumps. The material of a solder bump may be, for example, an alloy containing lead (Pb), an alloy of tin (Sn) and Au, an alloy of Sn and Cu, an alloy of Sn and silver (Ag), an alloy of Sn, Ag, and Cu, or the like.

The underfill resin 75 fills a gap between the wiring substrate 10 and the semiconductor chip 70. The material of the underfill resin 75 may be, for example, an insulating resin such as an epoxy resin.

The external connection terminals 76 are formed on the external connection pads 46P of the wiring substrate 10. The external connection terminals 76 are, for example, connection terminals for electrical connection to pads arranged on a mounting board such as a motherboard (not illustrated). The external connection terminals 76 may be, for example, solders ball or lead pins. In the present example, the external connection terminals 76 are solder balls.

### Method for Manufacturing Wiring Substrate 10

A method for manufacturing the wiring substrate 10 will now be described. To facilitate understanding, portions that will become elements of the wiring substrate 10 are given the same reference characters as the final elements.

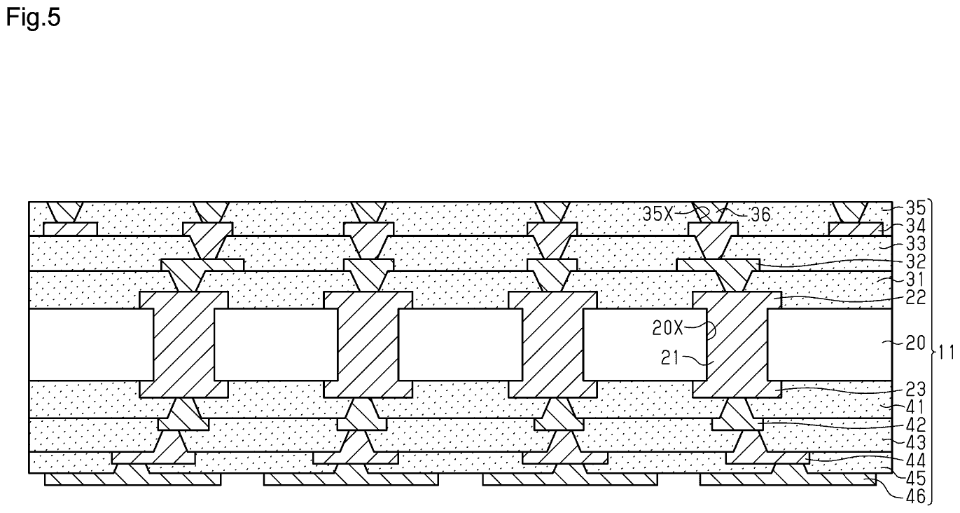

First, in the step illustrated in FIG. 5, a structural body is prepared by sequentially stacking the wiring layer 22, the insulating layer 31, the wiring layer 32, the insulating layer 33, the wiring layer 34, the insulating layer 35, and the via wiring 36 on the upper surface of the core substrate 20. Further, the wiring layer 23, the insulating layer 41, the wiring layer 42, the insulating layer 43, the wiring layer 44, the insulating layer 45, and the wiring layer 46 are sequentially stacked on the lower surface of the core substrate 20. Such a structural body may be manufactured by a typical manufacturing process. Thus, the process will not be described in detail.

Then, the upper surface of the insulating layer 35 and the upper end surface of the via wiring 36 are polished by a chemical mechanical polishing (CMP) process or the like. Thus, the upper surface of the insulating layer 35 becomes flush with the upper surface of the via wiring 36. Further, the upper surface of the insulating layer 35 is smoothed by polishing the upper surface of the insulating layer 35. For example, the arithmetic mean roughness Ra of the upper surface of the insulating layer 35 prior to polishing may be approximately 300 nm to 400 nm, and the arithmetic mean roughness Ra of the upper surface of the insulating layer 35 subsequent to polishing may be approximately 15 nm to 40 nm. Accordingly, the upper surface of the insulating layer 35 is polished and smoothed. In this manner, the upper surface of the insulating layer 35 and the upper end surface of the via wiring 36 become polished surfaces. The above-described process manufactures the wiring structure 11.

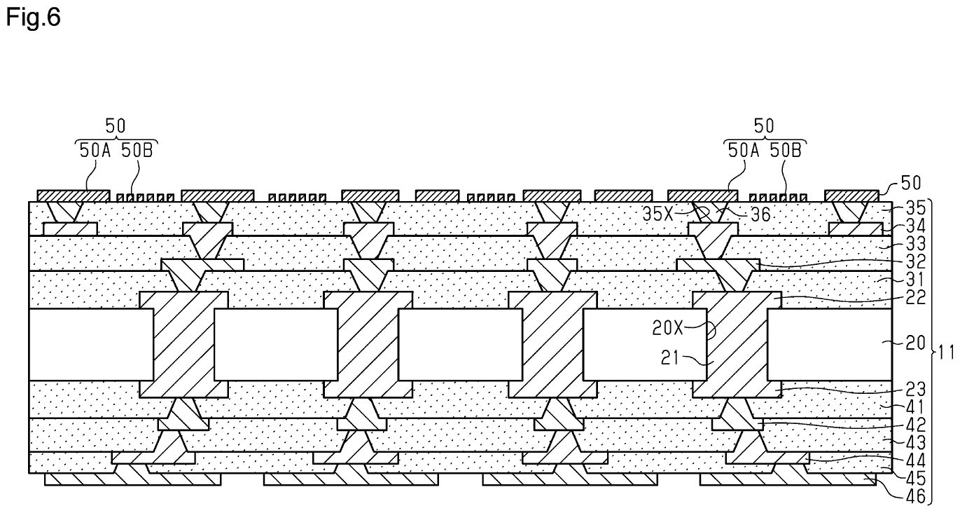

In the step illustrated in FIG. 6, the wiring layer 50 is formed on the upper surface of the insulating layer 35. The wiring layer 50 may be formed by any type of wiring forming process such as a subtractive process or a semi-additive process. The wiring layer 50 includes the wiring pattern 50A and the wiring pattern 50B.

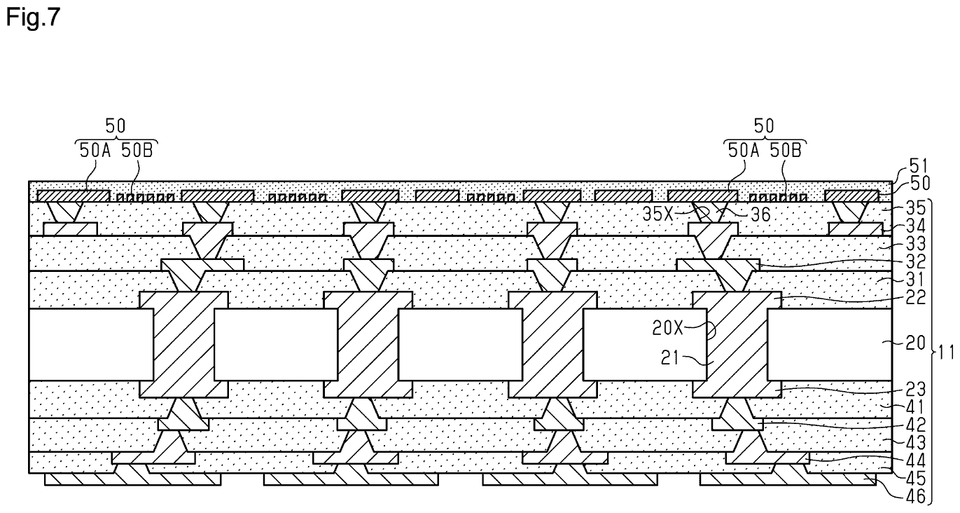

In the step illustrated in FIG. 7, the insulating layer 51 is formed on the upper surface of the insulating layer 35 to cover the wiring layer 50. When using a resin film as the insulating layer 51, for example, the upper surface of the insulating layer 35 is laminated with a resin film through thermocompression bonding to form the insulating layer 51. The resin film may be, for example, a film of a photosensitive resin such as a phenol resin or a polyimide resin. When using a liquid or a paste of insulating resin as the insulating layer 51, for example, the upper surface of the insulating layer 35 is coated with a liquid or paste of insulating resin by spin coating or the like to form the insulating layer 51. The liquid or paste of insulating resin may be, for example, a liquid or paste of a photosensitive resin such as a phenol resin or a polyimide resin. The insulating layer 51 is in an uncured state in the step illustrated in FIG. 7.

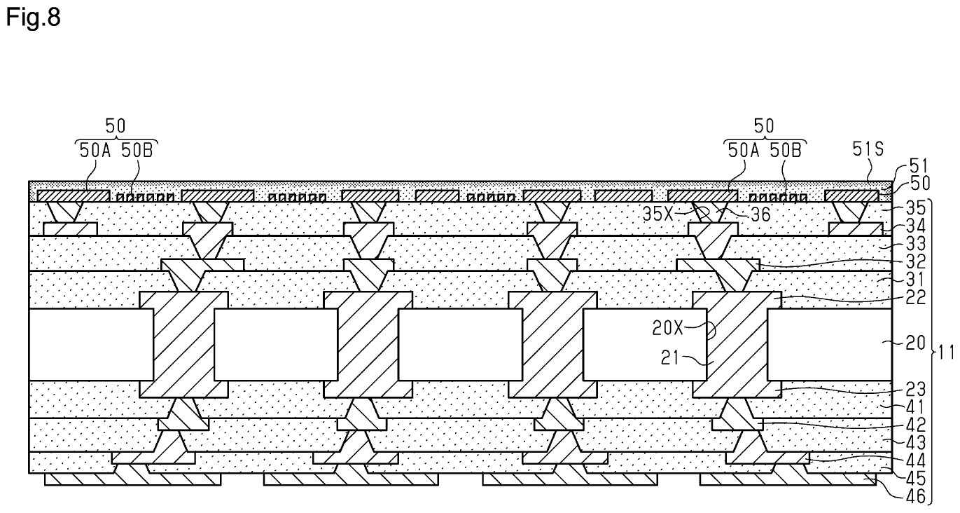

In the step illustrated in FIG. 8, only a surface layer 51S of the insulating layer 51 is cured. For example, a curing process is performed on the uncured insulating layer 51 in an atmospheric temperature of approximately 150° C. to 200° C. to cure only the surface layer 51S of the insulating layer 51. In the step illustrated in FIG. 8, the curing process is performed so as not to cure an inner layer portion of the insulating layer 51 that is located inward from the surface layer 51S. For example, the processing time of the curing is set such that the inner layer portion of the insulating layer 51 is not cured. Thus, the inner layer portion of the insulating layer 51 is in an uncured state in the step illustrated in FIG. 8.

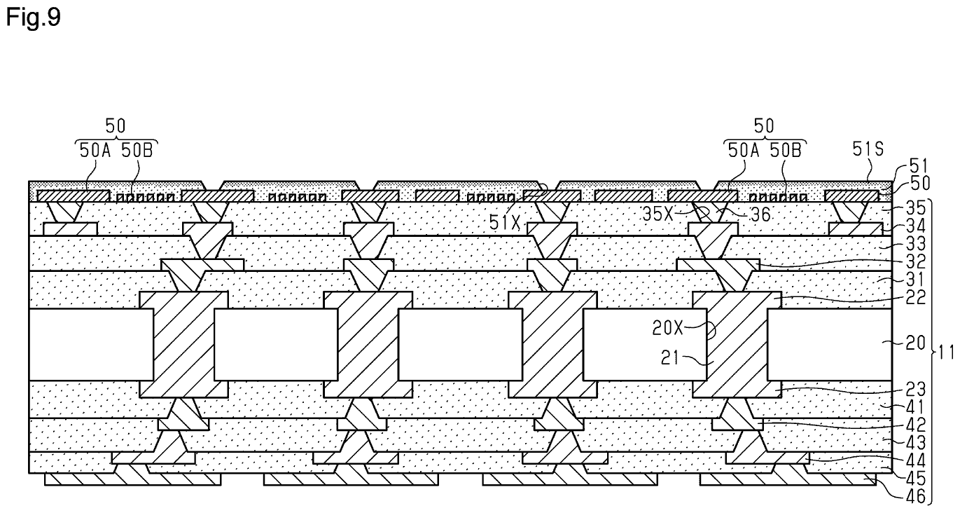

In the step illustrated in FIG. 9, the through holes 51X are formed in the insulating layer 51 to expose parts of the upper surface of the wiring layer 50. The through holes 51X may be formed, for example, by laser drilling using a CO₂ laser, a UV-YAG laser, or the like. When the through holes 51X are formed by laser drilling, a desmear process is performed to remove resin smears from the surface of the wiring layer 50 exposed at the bottom of each through hole 51X.

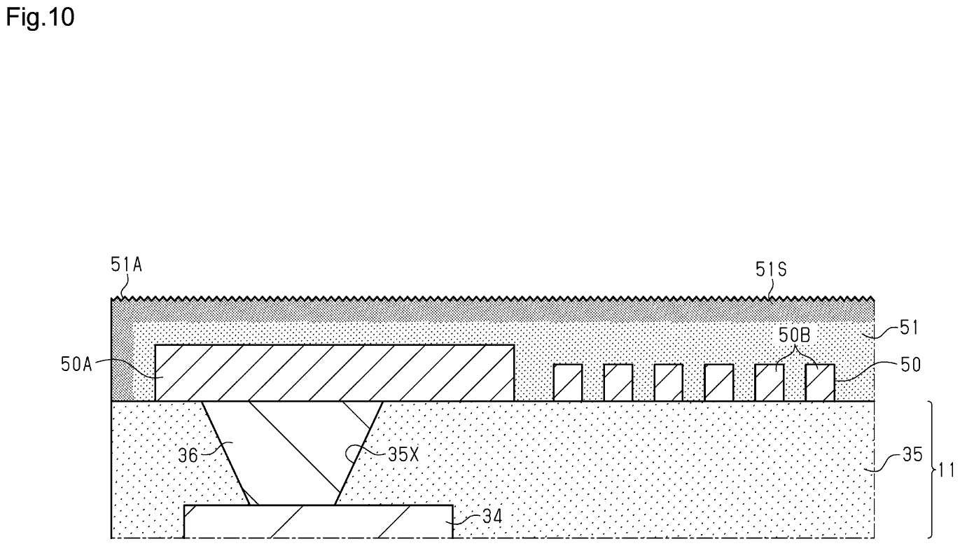

As illustrated in FIG. 10, the desmear process roughens the upper surface of the insulating layer 51 and the wall surface of each through hole 51X (refer to FIG. 9). This forms the entire upper surface of the insulating layer 51 as the roughened surface 51A. In this case, the roughened surface 51A may have surface roughness that corresponds to an arithmetic mean height Sa of, for example, 200 nm or less. The surface roughness of the roughened surface 51A is set to a level that does not adversely affect formation of fine wiring in a subsequent step. In the present example, the upper surface of the insulating layer 51 is roughened by a desmear process. Alternatively, the upper surface of the insulating layer 51 may be roughened by, for example, a plasma treatment such as O₂ plasma ashing.

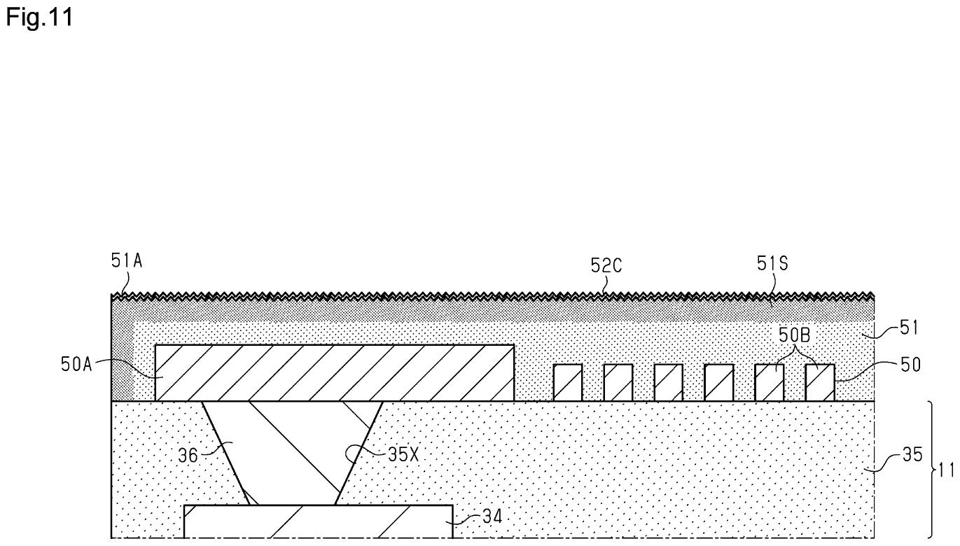

In the step illustrated in FIG. 11, the seed layer 52C is formed to cover the entire upper surface of the insulating layer 51 and the entire wall surface of each through holes 51X (refer to FIG. 9). The seed layer 52C may be formed by, for example, sputtering or electroless plating. When forming the seed layer 52C by sputtering, for example, titanium (Ti) is first sputtered and deposited on the upper surface of the insulating layer 51 so that the upper surface of the insulating layer 51 is covered by a Ti layer. Subsequently, copper is sputtered and deposited on the Ti layer to form a Cu layer. This forms the seed layer 52C with a double-layered structure (Ti layer/Cu layer). Alternatively, when forming the seed layer 52C by electroless plating, for example, electroless copper plating may be performed to form the seed layer 52C with a Cu layer (single-layered structure). The seed layer 52C extends along the roughened surface 51A of the insulating layer 51.

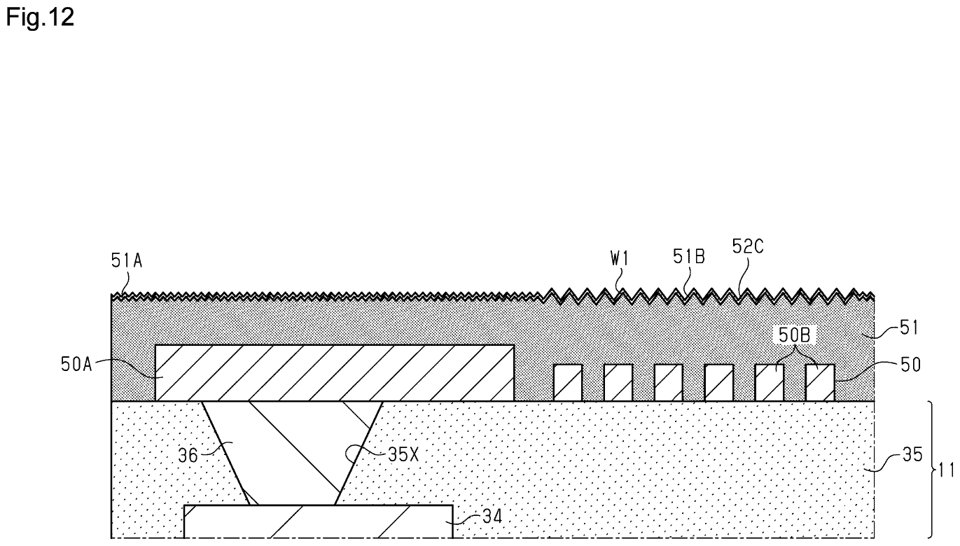

In the step illustrated in FIG. 12, the entire insulating layer 51 is cured. For example, a curing process is performed on the insulating layer 51 in an atmospheric temperature of approximately 150° C. to 200° C. to entirely cure the insulating layer 51. That is, the inner layer portion of the insulating layer 51 is cured. Then, when the temperature returns to normal temperature, the components of the structural body illustrated in FIG. 12 contract. In this case, buckling occurs in an upper part of the insulating layer 51 and the seed layer 52C in accordance with a difference between an elastic modulus of the insulating layer 51 and an elastic modulus of the seed layer 52C. In the structural body illustrated in FIG. 12, the seed layer 52C having a higher elasticity than the insulating layer 51 is formed on the upper surface of the insulating layer 51 having a relatively low elasticity. A contraction force when the low-elasticity insulating layer 51 returns to normal temperature is greater than a contraction force when the high-elasticity seed layer 52C returns to normal temperature. Such a difference in contraction force between the insulating layer 51 and the seed layer 52C applies compression stress to the insulating layer 51 and the seed layer 52C in a direction parallel to the surfaces. This compression stress causes buckling in the upper part of the insulating layer 51 and the seed layer 52C. Such buckling is likely to occur in a region where a difference between an elastic modulus of a base layer (wiring layer 50 and insulating layer 51) and an elastic modulus of a surface layer (seed layer 52C) is relatively large. In the base layer, a decrease in the volume percent of the wiring layer 50, which has a relatively high elasticity, increases the volume percent of the insulating layer 51, which has a relatively low elasticity, thereby lowering the elastic modulus of the entire base layer. Thus, the elastic modulus of the entire base layer is lower in a region where the wiring pattern 50B, which has a smaller volume than the wiring pattern 50A, is formed, compared to a region where the wiring pattern 50A is formed. Therefore, in the region where the wiring pattern 50B is formed, buckling occurs in the upper part of the insulating layer 51 and the seed layer 52C where the difference between the elastic modulus of the base layer and the elastic modulus of the seed layer 52C, which corresponds to the surface layer, is increased. As a result, the wrinkle pattern W1 resulting from the buckling is formed on the upper surface of the insulating layer 51 in the region where the wiring pattern 50B is formed, and in turn, the roughened surface 51B including the wrinkle pattern W1 is formed.

Typically, a wavelength λ of the wrinkle pattern W1, that is, the width of the wrinkle pattern W1, is determined by the following expression. In the following expression, “E1” represents the Young's modulus of the surface layer (seed layer 52C), “E2” represents the Young's modulus of the base layer (wiring layer 50 and insulating layer 51), and “h” represents the thickness of the surface layer (seed layer 52C).

λ∝h(E1/E2)^{1/3}

As apparent from the above expression, the wavelength λ of the wrinkle pattern W1 may be controlled by varying the difference in Young's modulus between the surface layer and the base layer or the thickness of the surface layer. This adjusts the roughness of the roughened surface 51B including the wrinkle pattern W1. For example, the wavelength λ of the wrinkle pattern W1 is increased by increasing the difference between Young's modulus E1 of the surface layer and Young's modulus E2 of the base layer.

In the present embodiment, Young's modulus E2 of the base layer is adjusted by varying the volume percent of the wiring layer 50. This controls a position where the wrinkle pattern W1 and the roughened surface 51B including the wrinkle pattern W1 are formed, and the roughness of the roughened surface 51B. In a region in which the roughness of the upper surface of the insulating layer 51 may be increased, the volume percent of the wiring layer 50 is decreased so that the roughened surface 51B including the wrinkle pattern W1 will be formed on the upper surface of the insulating layer 51. In a region in which the roughness of the upper surface of the insulating layer 51 may be increased, for example, the wiring pattern 50B having a relatively small volume is formed. Alternatively, the wiring layer 50 is not formed in that region. In a region in which the roughness of the upper surface of the insulating layer 51 may be maintained as relatively small, the volume percent of the wiring layer 50 is increased so that the upper surface of the insulating layer 51 will be maintained as the roughened surface 51A. In a region in which the roughness of the upper surface of the insulating layer 51 may be maintained as relatively small, for example, the wiring pattern 50A having a relatively large volume is formed. The region in which the roughness of the upper surface of the insulating layer 51 may be maintained as relatively small is, for example, a region in which fine wiring is to be formed on the upper surface of the insulating layer 51.

As a result of such adjustments, the roughened surface 51A remains in the region where the wiring pattern 50A is formed, and the roughened surface 51B including the wrinkle pattern W1 is formed in the region where the wiring pattern 50B is formed. The above-described process forms the roughened surfaces 51A and 51B having different roughnesses on the upper surface of the insulating layer 51. In this case, the seed layer 52C formed on the upper surface of the insulating layer 51 is shaped in conformance with the roughened surface 51A and the roughened surface 51B. Thus, the upper surface of the seed layer 52C has roughened surfaces that are the same as the roughened surface 51A and the roughened surface 51B.

When forming the seed layer 52C by a dry process such as sputtering, the seed layer 52C is formed under a temperature environment of approximately 150° C. to 200° C. so that the entire insulating layer 51 may be cured as the seed layer 52C is formed. This eliminates the need to perform a curing process separately from when forming the seed layer 52C by a dry process.

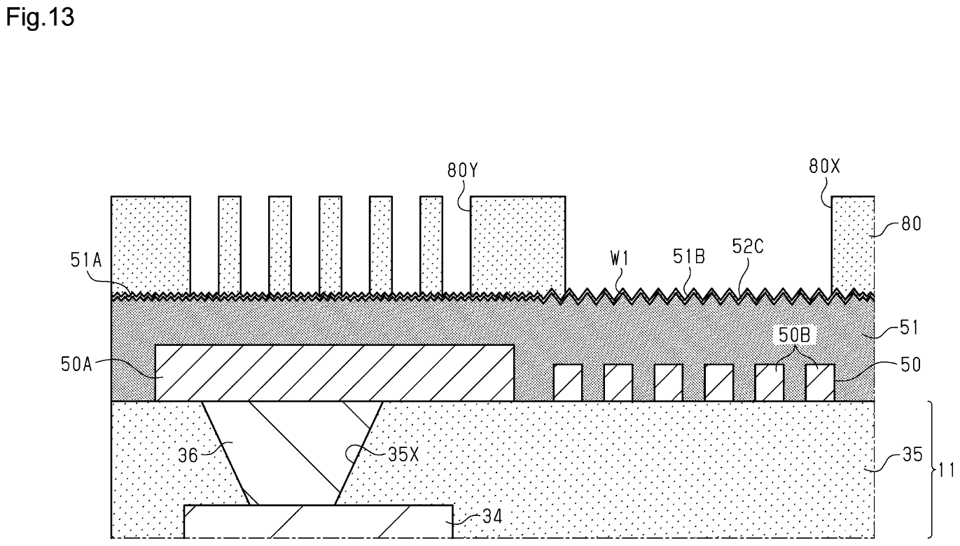

In the step illustrated in FIG. 13, a resist layer 80 is formed on the seed layer 52C. The resist layer 80 includes opening patterns 80X and 80Y at given locations. The opening pattern 80X exposes parts of the seed layer 52C located in the region in which the wiring pattern 52A (refer to FIG. 2) is formed. That is, the opening pattern 80X exposes the seed layer 52C formed on the roughened surface 51B. The opening pattern 80Y exposes parts of the seed layer 52C located in the region in which the wiring pattern 52B (refer to FIG. 2) is formed. That is, the opening pattern 80Y exposes the seed layer 52C formed on the roughened surface 51A. The material of the resist layer 80 may be, for example, a material that is resistant to electrolytic plating performed in a subsequent process. The resist layer 80 may use, for example, a photosensitive dry film resist or a liquid photoresist. Examples of such a resist material include a novolac resin, an acrylic resin, or the like. When using a photosensitive dry film resist, the upper surface of the seed layer 52C is laminated with a dry film through thermocompression bonding, and then the dry film is patterned by photolithography to form the resist layer 80 including the opening patterns 80X and 80Y. When using a liquid photoresist, the resist layer 80 may be formed through a similar process.

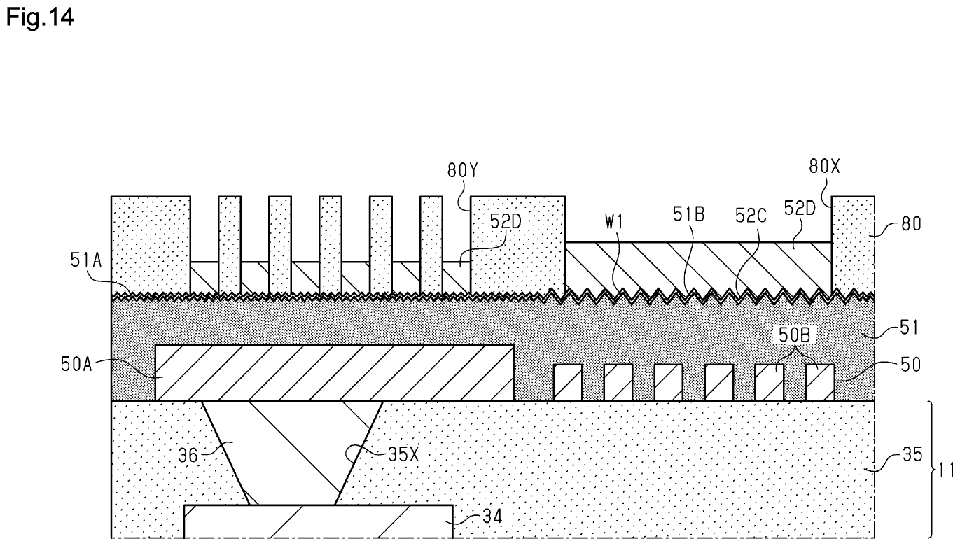

In the step illustrated in FIG. 14, electrolytic plating is performed on the seed layer 52C using the resist layer 80 as a plating mask and the seed layer 52C as a plating power feeding layer. That is, electrolytic plating (electrolytic Cu plating) is performed on the upper surface of the seed layer 52C exposed from the opening patterns 80X and 80Y of the resist layer 80. This forms the metal layer 52D in the opening patterns 80X and 80Y. In this case, the metal layer 52D in the opening pattern 80X is formed to be thicker than the metal layer 52D in the opening pattern 80Y. Although not illustrated, the metal layer 52D is also formed on the seed layer 52C in the through holes 51X (refer to FIG. 9) and fills the through holes 51X.

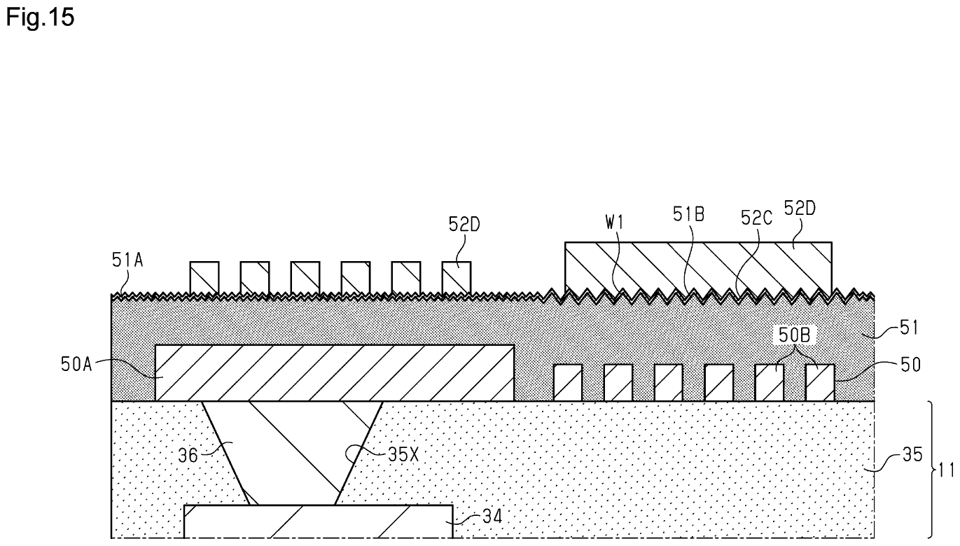

In the step illustrated in FIG. 15, the resist layer 80 in FIG. 14 is removed using an alkali stripping solution (e.g., organic amine stripping solution, caustic soda, acetone, or ethanol).

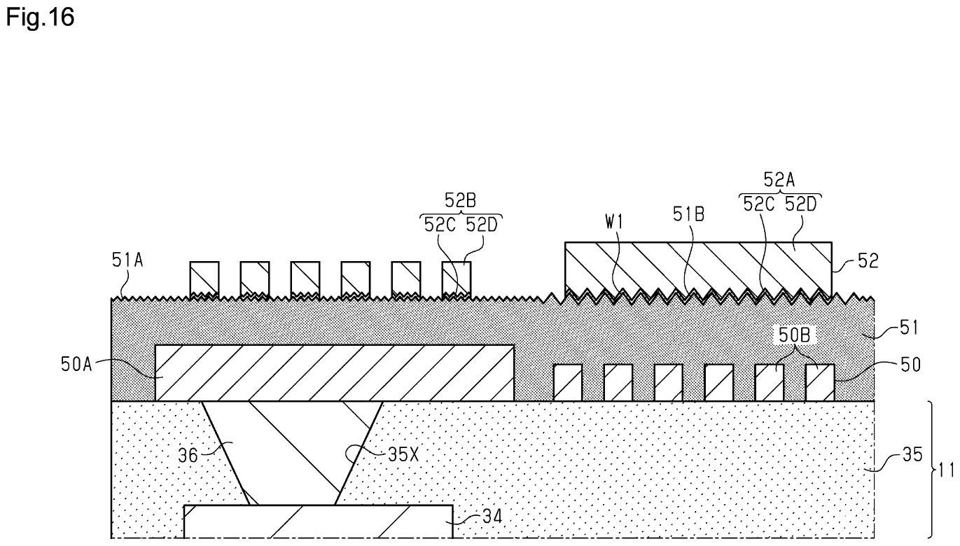

In the step illustrated in FIG. 16, etching is performed using the metal layer 52D as an etching mask to remove unnecessary portions of the seed layer 52C. As a result, the wiring pattern 52A including the seed layer 52C and the metal layer 52D is formed on the roughened surface 51B, and the wiring pattern 52B including the seed layer 52C and the metal layer 52D is formed on the roughened surface 51A. In this manner, the wiring layer 52 including the wiring patterns 52A and 52B is formed on the upper surface of the insulating layer 51.

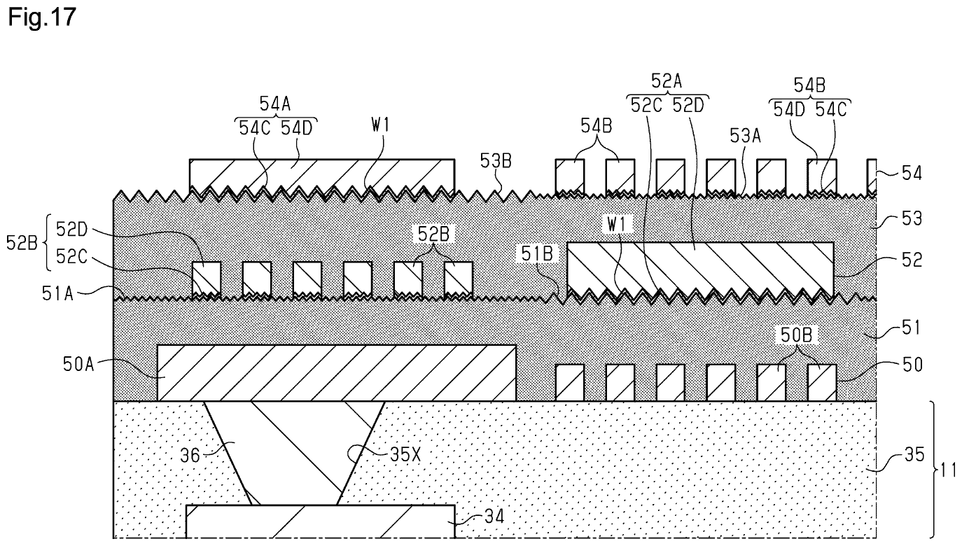

In the step illustrated in FIG. 17, the insulating layer 53 is formed on the upper surface of the insulating layer 51 to cover the wiring layer 52. The upper surface of the insulating layer 53 includes the roughened surface 53A located above the wiring pattern 52A, and the roughened surface 53B located above the wiring pattern 52B. The insulating layer 53 may be formed through the same process as the steps illustrated in FIGS. 7 to 12.

Then, the wiring layer 54 is formed on the upper surface of the insulating layer 53. The wiring layer 54 includes the wiring pattern 54A formed on the roughened surface 53B, and the wiring pattern 54B formed on the roughened surface 53A. The wiring patterns 54A and 54B include the seed layer 54C formed on the roughened surfaces 53B and 53A and the metal layer 54D formed on the seed layer 54C. The wiring layer 54 may be formed through the same process as the steps illustrated in FIGS. 13 to 16.

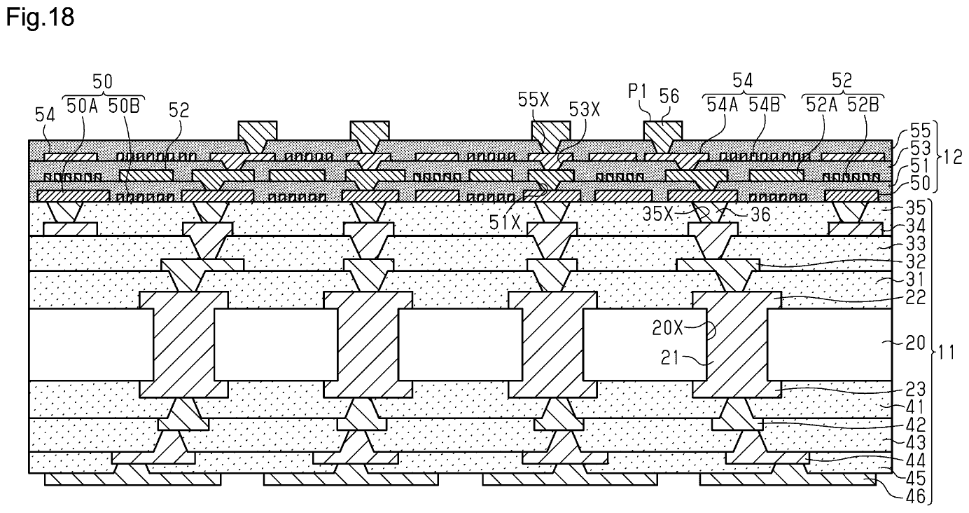

In the step illustrated in FIG. 18, the insulating layer 55 including the through holes 55X is formed on the upper surface of the insulating layer 53. The through holes 55X expose parts of the upper surface of the wiring layer 54. When using a resin film as the insulating layer 55, for example, the upper surface of the insulating layer 53 is laminated with a resin film through thermocompression bonding, and then the resin film is patterned by photolithography to form the insulating layer 55. The resin film may be, for example, a film of a photosensitive resin such as a phenol resin or a polyimide resin. When using a liquid or a paste of insulating resin as the insulating layer 55, for example, the upper surface of the insulating layer 53 is coated with a liquid or paste of insulating resin by spin coating or the like, and then the insulating resin is patterned by photolithography to form the insulating layer 55. The liquid or paste of insulating resin may be, for example, a liquid or paste of a photosensitive resin such as a phenol resin or a polyimide resin.

Subsequently, for example, a semi-additive process is performed to form the via wiring filling the through holes 55X and the wiring layer 56 including the pads P1. The pads P1 are formed on the upper surface of the insulating layer 55 and are electrically connected to the wiring layer 54 by the via wiring in the through holes 55X. A surface-processed layer may be formed, if necessary, on the surface of the pads P1. The above-described manufacturing process arranges the wiring structure 12 on the upper surface of the insulating layer 35, which is the uppermost layer of the wiring structure 11.

Then, the solder resist layer 13 illustrated in FIG. 1 is formed on the lower surface of the insulating layer 45. The solder resist layer 13 includes the openings 13X that expose the external connection pads 46P defined at specified locations of the wiring layer 46 of the wiring structure 11. The above-described manufacturing process manufactures the wiring substrate 10 illustrated in FIG. 1.

The present embodiment has the following advantages.

(1) The wiring substrate 10 includes the wiring layer 50, the insulating layer 51, the wiring layer 52, and the insulating layer 53. The insulating layer 51 covers the wiring layer 50. The wiring layer 52 is formed on the upper surface of the insulating layer 51 and is electrically connected to the wiring layer 50. The insulating layer 53 is formed on the upper surface of the insulating layer 51 and covers the wiring layer 52. The insulating layer 51 includes the roughened surface 51A and the roughened surface 51B having a greater roughness than the roughened surface 51A. The roughened surface 51B includes the wrinkle pattern W1 resulting from buckling. The volume percent of the wiring layer 50 located in the first region that overlaps the roughened surface 51A in plan view is greater than the volume percent of the wiring layer 50 located in the second region that overlaps the roughened surface 51B in plan view.

With this configuration, the roughened surface 51A and the roughened surface 51B having a greater roughness than the roughened surface 51A are arranged on the upper surface of the insulating layer 51. Accordingly, the roughened surfaces 51A and 51B having different roughnesses are arranged on the same plane of the upper surface of the insulating layer 51. In this case, the roughened surface 51B includes the wrinkle pattern W1 resulting from buckling. Such buckling is caused by adjusting the difference between the elastic modulus of the base layer and the elastic modulus of the surface layer. This allows the roughened surface 51B to be formed without increasing the steps in the manufacturing process. The roughened surfaces 51A and 51B are readily formed compared to when, for example, the roughening treatment is performed a number of times to form roughened surfaces having different roughnesses and a resist layer needs to be arranged as a mask each time roughening treatment is performed.

(2) The roughened surface 51A is formed in the first region in which the volume percent of the wiring layer 50 is relatively large, and the roughened surface 51B including the wrinkle pattern W1 is formed in the second region in which the volume percent of the wiring layer 50 is relatively small. Thus, the volume percent of the wiring layer 50 may be adjusted to control the position where the wrinkle pattern W1 is formed, that is, the position where the roughened surface 51B is formed. This allows the roughened surface 51B having a relatively large roughness to be readily formed at a desired location by adjusting the design of the wiring layer 50.

(3) The wiring layer 52 is formed on the upper surface of the insulating layer 51, which includes the roughened surfaces 51A and 51B, and the insulating layer 53 is formed on the upper surface of the insulating layer 51 to cover the wiring layer 52. Thus, when the wiring layer 52 is formed on the roughened surface 51B having a relatively large roughness, the contact area between the wiring layer 52 and the roughened surface 51B is increased. This improves the adhesion between the wiring layer 52 and the insulating layer 51. In the same manner, when the insulating layer 53 is formed on the roughened surface 51B having a relatively large roughness, the contact area between the insulating layer 53 and the roughened surface 51B is increased. This improves the adhesion between the insulating layer 53 and the insulating layer 51. In contrast, fine wiring part of the wiring layer 52 is formed on the roughened surface 51A having a relatively small roughness.

(4) The volume of the wiring pattern 50A arranged in the first region that overlaps the roughened surface 51A in plan view is greater than the volume of the wiring pattern 50B arranged in the second region that overlaps the roughened surface 51B in plan view. This configuration readily increases the volume percent of the wiring layer 50 located in the first region to be greater than the volume percent of the wiring layer 50 located in the second region.

(5) The wiring pattern 50A is thicker than the wiring pattern 50B. The upper surface of the wiring pattern 50A has a greater area than the upper surface of the wiring pattern 50B. These configurations readily increase the volume of the wiring pattern 50A to be greater than the volume of the wiring pattern 50B. This, in turn, increases the volume percent of the wiring layer 50 located in the first region to be greater than the volume percent of the wiring layer 50 located in the second region.

(6) The wrinkle pattern W1 is maze-like in plan view. Such a wrinkle pattern W1 includes wrinkles extending in random directions. When the wiring layer 52 including the wrinkle pattern W1 is formed on the roughened surface 51B, the wrinkle pattern W1 increases the contact area between the insulating layer 51 and the wiring layer 52. Accordingly, the contact area between the insulating layer 51 and the wiring layer 52 is increased in the random directions in which the wrinkles of the wrinkle pattern W1 extend, thereby improving the adhesion between the insulating layer 51 and the wiring layer 52. Therefore, even when stress is applied to the interface between the roughened surface 51B and the wiring layer 52 in various directions, cracks will not be formed by the stress in the interface between the roughened surface 51B and the wiring layer 52.

(7) The wiring layer 52 includes the wiring pattern 52B formed on the roughened surface 51A, and the wiring pattern 52A formed on the roughened surface 51B. The wiring pattern 52B is finer wiring than the wiring pattern 52A. This configuration forms the wiring pattern 52B, which is fine wiring, on the roughened surface 51A having a relatively a small roughness. This allows the wiring pattern 52B, which is fine wiring, to be formed on the upper surface of the insulating layer 51 even when the upper surface of the insulating layer 51 includes the roughened surface 51B having a relatively large roughness.

(8) The wiring pattern 52A having a greater surface area than the wiring pattern 52B is formed on the roughened surface 51B having a relatively large roughness. This configuration improves the adhesion between the insulating layer 51 and the wiring pattern 52A, which has a relatively large surface area as a plane layer or a land does.

### OTHER EMBODIMENTS

The above embodiment may be modified as described below. The above embodiment and the following modifications may be combined as long as the combined modifications remain technically consistent with each other.

The planar shape of the wrinkle pattern W1 in the above embodiment may be changed. For example, the wrinkle pattern W1 may include stripes in plan view. In this case, each stripe in the wrinkle pattern W1 may extend in any direction. The planar shape of the wrinkle pattern W1 may be controlled by adjusting, for example, the contraction direction of the insulating layers 51 and 53, the degree of density difference between the wiring layers 50 and 52, or the difference in Young's modulus between the base layer and the surface layer.

In the above embodiment, the wiring pattern 50A is thicker than the wiring pattern 50B. However, for example, the wiring pattern 50A may have the same thickness as the wiring pattern 50B as long as the wiring pattern 50A has a greater volume than the wiring pattern 50B. The same applies to the wiring patterns 52A and 52B.

In the above embodiment, the upper surface of the wiring pattern 50A has a greater area than the upper surface of the wiring pattern 50B. However, for example, the upper surface of the wiring pattern 50A may have the same area as the upper surface of the wiring pattern 50B as long as the wiring pattern 50A has a greater volume than the wiring pattern 50B. The same applies to the wiring patterns 52A and 52B.

In the above embodiment, the wiring pattern 50B is finer wiring than the wiring pattern 50A. However, there is no limitation to such a configuration.

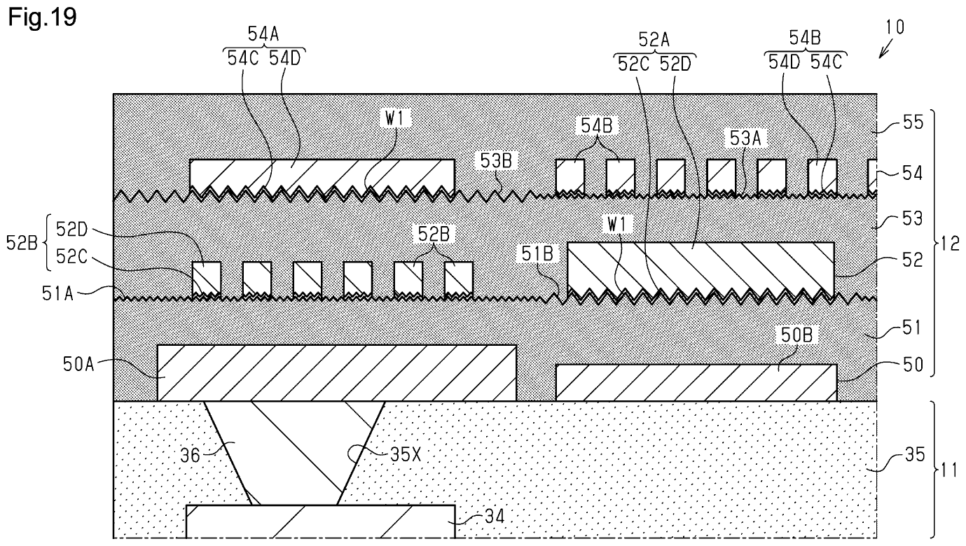

As illustrated in FIG. 19, the wiring pattern 50B may be, for example, a solid pattern in the same manner as the wiring pattern 50A. In this case, the wiring pattern 50B may be thinner than the wiring pattern 50A so that the volume of the wiring pattern 50B becomes less than the volume of the wiring pattern 50A. The same applies to the wiring patterns 52A and 52B.

In the above embodiment, the wiring pattern 50B is located below the roughened surface 51B including the wrinkle pattern W1. However, for example, the wiring layer 50 does not have to be arranged below the roughened surface 51B.

In the above embodiment, roughened surfaces having different roughnesses may be arranged on the upper surface of the insulating layer 55.

In the above embodiment, the roughened surfaces 51A, 51B, 53A, and 53B having different roughnesses are arranged on the insulating layers 51 and 53 of the wiring structure 12. Instead of or in addition to these, for example, roughened surfaces having different roughnesses may be arranged on the insulating layer 31, 33, 41, 43, and/or 45 of the wiring structure 11.

The number of wiring layers, the wiring layout, or the like of the wiring structure 11 of the above embodiment may be modified in any manner. Further, the number of insulating layers of the wiring structure 11 may be modified in any manner.

In the above embodiment, the wiring layers 22 and 23 located above and below the core substrate 20 are electrically connected to each other by the through-electrodes 21 filling the through holes 20X of the core substrate 20. Alternatively, the wiring layers 22 and 23 located above and below the core substrate 20 may be electrically connected to each other by, for example, a through-hole plating layer formed on the wall of each through hole 20X. In this case, resin may be formed on the through-hole plating layer and fill the through holes 20X.

The wiring structure 11 may be omitted.

The number of wiring layers, the wiring layout, or the like of the wiring structure 12 of the above embodiment may be modified in any manner. Further, the number of insulating layers of the wiring structure 12 may be modified in any manner.

In the above embodiment, the solder resist layer 13 is described as an example of protective insulating layer that corresponds to the outermost insulating layer of the wiring substrate 10. However, a protective insulating layer may be formed from any type of photosensitive insulating resin.

The solder resist layer 13 of the above embodiment may be omitted.

In the above embodiment, the semiconductor chip 70 is mounted on the wiring substrate 10. Alternatively, an electronic component other than the semiconductor chip 70, for example, a chip component such as a chip capacitor, a chip resistor, or a chip inductor, or an electronic component such as a crystal oscillator may be mounted on the wiring substrate 10.

The mounting mode (e.g., flip-chip mounting, wire-bonding mounting, solder mounting, or combination of these) of electronic components, such as the semiconductor chip 70, the chip component, and the crystal oscillator, may be changed.

### Clauses

This disclosure further encompasses the following embodiments.

1. A method for manufacturing a wiring substrate, the method including:
forming a first wiring layer;
forming a first insulating layer that covers the first wiring layer;
forming a first roughened surface on an upper surface of the first insulating layer by performing a roughening treatment on the upper surface of the first insulating layer;
forming a seed layer on the upper surface of the first insulating layer; and
forming a second roughened surface on a portion of the upper surface of the first insulating layer, the second roughened surface including a wrinkle pattern resulting from buckling that occurs in accordance with a difference between an elastic modulus of a base layer and an elastic modulus of the seed layer, the base layer including the first wiring layer and the first insulating layer, where:
the forming the second roughened surface includes forming the first roughened surface and the second roughened surface on the upper surface of the first insulating layer, the first roughened surface being arranged in a region outside the portion where the second roughened surface is formed; and
a volume percent of the first wiring layer located in a first region that overlaps the first roughened surface in plan view is greater than a volume percent of the first wiring layer located in a second region that overlaps the second roughened surface in plan view.

2. The method according to clause 1, in which:
the forming the first insulating layer includes forming the first insulating layer that entirely covers the first wiring layer; and
the forming the first roughened surface includes
curing only a surface layer of the first insulating layer,
forming a through hole by laser drilling that extends through the first insulating layer in a thickness-wise direction and exposes part of an upper surface of the first wiring layer, and
performing a desmear process to remove a resin smear from the upper surface of the first wiring layer exposed from the through hole and to roughen the upper surface of the first insulating layer to form the first roughened surface.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A wiring substrate, comprising:
a first wiring layer;
a first insulating layer covering the first wiring layer; and
a second wiring layer formed on an upper surface of the first insulating layer and electrically connected to the first wiring layer, wherein:
the upper surface of the first insulating layer includes a first roughened surface and a second roughened surface having a roughness that is greater than that of the first roughened surface;
the second roughened surface includes a wrinkle pattern resulting from buckling; and
a volume percent of the first wiring layer located in a first region that overlaps the first roughened surface in plan view is greater than a volume percent of the first wiring layer located in a second region that overlaps the second roughened surface in plan view.

2. The wiring substrate according to claim 1, wherein:
the first wiring layer includes a first wiring pattern arranged in the first region, and a second wiring pattern arranged in the second region; and
a volume of the first wiring pattern is greater than a volume of the second wiring pattern.

3. The wiring substrate according to claim 2, wherein the first wiring pattern is thicker than the second wiring pattern.

4. The wiring substrate according to claim 2, wherein an upper surface of the first wiring pattern has an area that is greater than that of an upper surface of the second wiring pattern.

5. The wiring substrate according to claim 2, wherein the second wiring pattern is fine wiring having a line-and-space that is smaller than that of the first wiring pattern.

6. The wiring substrate according to claim 1, wherein the wrinkle pattern is maze-like in plan view.

7. The wiring substrate according to claim 1, wherein:
the second wiring layer includes a third wiring pattern formed on the first roughened surface and a fourth wiring pattern formed on the second roughened surface; and
the third wiring pattern is fine wiring having a line-and-space that is smaller than that of the fourth wiring pattern.

8. The wiring substrate according to claim 7, wherein:
the third wiring pattern includes a first seed layer formed on the first roughened surface and a first metal layer formed on the first seed layer; and
the fourth wiring pattern includes a second seed layer formed on the second roughened surface and a second metal layer formed on the second seed layer.

9. The wiring substrate according to claim 1, wherein:
the first wiring layer includes a first wiring pattern that overlaps the first roughened surface in plan view and a second wiring pattern that overlaps the second roughened surface in plan view, the second wiring pattern having a wiring density that is lower than that of the first wiring pattern;
in a region located immediately below the first roughened surface, the first wiring pattern has a volume percentage that is higher than that of the first insulating layer; and
in a region located immediately below the second roughened surface, the first insulating layer has a volume percentage that is higher than that of the second wiring pattern.

10. The wiring substrate according to claim 9, further comprising:
a second insulating layer covering the second wiring layer, wherein:
the second wiring layer includes a third wiring pattern located on the first roughened surface and a fourth wiring pattern located on the second roughened surface, the fourth wiring pattern having a wiring density that is higher than that of the third wiring pattern;
in a region located immediately above the first roughened surface, the second insulating layer has a volume percentage that is higher than that of the third wiring pattern; and
in a region located immediately above the second roughened surface, the fourth wiring pattern has a volume percentage that is higher than that of the second insulating layer.

11. The wiring substrate according to claim 10, wherein:
an upper surface of the second insulating layer includes a third roughened surface that overlaps the first roughened surface in plan view and a fourth roughened surface that overlaps the second roughened surface in plan view.
